(19) United States
(12) Patent Application Publication
(10) Pub. No.: US 2006/0079056 A1
(43) Pub. Date: Apr. 13, 2006

(54) Semiconductor structures having a strained silicon layer on a silicon-germanium layer and related fabrication methods

(76) Inventors: Young-Pil Kim, Gyeonggi-do (KR); Sun-Ghil Lee, Gyeonggi-do (KR); Yu-Gyun Shin, Gyeonggi-do (KR); Jong-Wook Lee, Gyeonggi-do (KR); In-Soo Jung, Gyeonggi-do (KR)

Correspondence Address: MYERS BIGEL SIBLEY & SAJOVEC, PO BOX 37428, RALEIGH, NC, 27627, US

(21) Appl. No.: 11/247,412

(22) Filed: Oct. 11, 2005

(30) Foreign Application Priority Data
Oct. 11, 2004 (KR) 2004-81105

(51) Int. Cl. H01L 21/336

(52) U.S. Cl. 438/285

(57) ABSTRACT

A semiconductor structure including a SiGe layer and a method of fabricating the same are provided. The structure includes a silicon layer heavily doped with impurities. A SiGe layer is disposed on the silicon layer. A strained silicon layer is disposed on the SiGe layer. The impurities may be boron. The boron in the silicon layer may have a concentration of 10¹⁶ to 10²⁰/cm³. Boron in the SiGe layer, diffused from the silicon substrate or directly doped, may suppress movement of misfit dislocation occurring in the SiGe layer toward the surface, thereby reducing a threading dislocation density near the surface of the strained silicon layer.

### CROSS-REFERENCE TO RELATED APPLICATION

This application claims priority under 35 U.S.C. § 119 from Korean Patent Application No. 2004-81105, filed on Oct. 11, 2004, the disclosure of which is hereby incorporated herein by reference in its entirety as if set forth fully herein.

### FIELD OF THE INVENTION

The present invention relates to semiconductor structures and, more particularly, to semiconductor structures that include silicon-germanium (SiGe) layers and related methods of fabricating such structures.

### BACKGROUND OF THE INVENTION

One potential method of improving the speed and/or integration level of certain types of semiconductor devices is to provide semiconductor layers having improved microscopic features. By way of example, the mobility of the electrons or holes that act as carriers in the channel of metal oxide semiconductor (MOS) transistors directly affects both the drain current and the switching speed of the transistors. As such, carrier mobility can directly impact the speed and/or integration levels of semiconductor devices that include MOS transistors.

One method that has been proposed for improving the carrier mobility is to form the channel of MOS transistors in a strained silicon layer. In particular, a SiGe layer that has a larger crystal lattice than a silicon layer is formed as a virtual substrate (e.g., a growth template) on a silicon substrate. A single crystalline silicon layer is epitaxially grown on the SiGe layer as a strained silicon layer. However, it has been found that threading dislocations that are introduced at the interface between the silicon substrate and the SiGe layer to compensate for the stress caused by the discrepancy in the lattice constants of silicon and SiGe may propagate to the upper surface of the strained silicon layer. These threading dislocations in the strained silicon layer may deteriorate the electrical characteristics of the strained silicon layer.

One potential method of reducing the density of threading dislocations in the strained silicon layer is to provide an SiGe layer that is sufficiently relaxed to compensate for the stress, which can suppress propagation of the threading dislocations to the surface of the strained silicon layer. Specifically, relaxed SiGe layers having a uniform germanium concentration have been formed to a thickness of a few micrometers (μm) on a graded SiGe layer with a vertical Ge concentration gradient. A strained silicon layer is then formed on the relaxed SiGe layer. Even with the use of such relaxed SiGe layers, the threading dislocation density at the surface of the strained silicon layer may be one million dislocations per square centimeter (10⁶/cm²) or more. Methods of forming relaxed SiGe layers by implanting hydrogen ions into a SiGe layer and then heat treating the layer are also known in the art as disclosed, for example, in U.S. Pat. Nos. 6,562,703 and 6,746,902.

### SUMMARY OF THE INVENTION

Pursuant to embodiments of the present invention, semiconductor structures having strained silicon layers with reduced threading dislocations at the surface thereof are provided, as well as methods of fabricating such structures.

Pursuant to certain embodiments of the present invention, semiconductor structures are provided that include a silicon layer, a silicon-germanium layer on the silicon layer, and a strained silicon layer on the silicon-germanium layer. At least one of the silicon layer or the silicon-germanium layer is heavily doped with impurities. The impurities may comprise, for example, boron. The silicon-germanium layer may have a boron concentration of between about 10¹²/cm³ to 10²⁰/cm³. The silicon layer may have a boron concentration of between about 10¹⁶/cm³ to about 10²⁰/cm³.

In certain embodiments of the present invention, the silicon layer may comprise a silicon substrate. In other embodiments, the silicon layer may be a single crystalline silicon layer on a silicon substrate. The silicon-germanium layer may comprise (a) a graded silicon-germanium layer that has a vertical germanium concentration gradient on the silicon layer and (b) a relaxed silicon-germanium layer that has a substantially uniform germanium concentration on the graded silicon-germanium layer. The graded silicon-germanium layer may have a boron concentration of, for example, between about 10¹²/cm³ to 10²⁰/cm³.

The graded silicon-germanium layer may, in certain embodiments, be represented by the chemical equation Si₁₋ₓGeₓ, where x has a value of approximately zero adjacent an interface between the silicon layer and the graded silicon-germanium layer and a value between about 0.15 and about 0.4 adjacent an interface between the graded silicon-germanium layer and the relaxed silicon-germanium layer. The relaxed silicon-germanium layer may, in certain embodiments, be represented by the chemical equation Si_{1-y}Ge_{y}, where y is approximately equal to the value of x at the interface between the graded silicon-germanium layer and the relaxed silicon-germanium layer.

In exemplary embodiments of the present invention, the strained silicon layer may be a single crystalline silicon layer having a thickness of about 10 nm to about 20 nm. The graded silicon-germanium layer may have a thickness of between about 0.1 microns to about 5 microns. The relaxed silicon-germanium layer may have a thickness of between about 0.1 microns to about 2 microns. The vertical germanium concentration gradient in the graded silicon-germanium layer may be between about 0.1 microns/10% to about 2.0 microns/10%. The upper surface of the strained silicon layer may have a dislocation density of less than 10⁵ dislocations per square centimeter.

Pursuant to further embodiments of the present invention, methods of fabricating a semiconductor structure are provided in which a silicon layer is prepared. A silicon-germanium layer is formed on the silicon layer. A strained silicon layer is formed on the silicon-germanium layer. In this method, at least one of the silicon layer or the silicon-germanium layer is formed to be heavily doped with impurities.

In certain embodiments of these methods, the impurities may comprise boron. In such embodiments, the boron in the silicon layer may have a concentration of between about 10¹⁶/cm³ to about 10²⁰/cm³. The silicon layer may comprise a silicon substrate that has been implanted with boron ions. In other embodiments, the silicon layer may be formed as a single crystalline silicon layer on a silicon substrate and then boron ions may be implanted into the single crystalline silicon layer. In still other embodiments, the silicon layer may be prepared by doping boron ions in situ during the epitaxial growth of a single crystalline silicon layer on a silicon substrate.

The silicon-germanium layer may be formed on the silicon layer by forming a graded silicon-germanium layer that has a vertical germanium concentration gradient on the silicon layer and then forming a relaxed silicon-germanium layer that has a substantially uniform germanium concentration on the graded silicon-germanium layer. Boron ions may be implanted into the graded silicon-germanium layer and/or boron ions may be doped in situ into the graded silicon-germanium layer during the formation of the graded silicon-germanium layer. The graded silicon-germanium layer and the relaxed silicon-germanium layer may, in certain embodiments, be represented by chemical equations, Si₁₋ₓGeₓ and Si_{1-y}Ge_{y}, respectively, where x has a value of approximately zero adjacent an interface between the silicon layer and the graded silicon-germanium layer and y adjacent an interface between the graded silicon-germanium layer and the relaxed silicon-germanium layer, and wherein y has a value of 0.15 to 0.4.

The strained silicon layer may be formed on the silicon-germanium layer by forming a strained single crystalline silicon layer on the silicon-germanium layer to a thickness of about 10 nm to about 20 nm via epitaxial growth. At least the graded silicon-germanium layer may have a boron concentration of between about 10¹²/cm³ to 10²⁰/cm³.

### BRIEF DESCRIPTION OF THE DRAWINGS

The above and other features and advantages of the present invention will become more apparent to those of ordinary skill in the art by the following detailed description of exemplary embodiments thereof with reference to the attached drawings in which:

FIGS. 1 and 2 are cross-sectional diagrams of semiconductor structures that include SiGe layers according to certain embodiments of the present invention;

FIGS. 3 and 4 are cross-sectional diagrams of semiconductor structures that include SiGe layers according to further embodiments of the present invention;

FIGS. 5 and 6 are cross-sectional diagrams of semiconductor structures that include SiGe layers according to additional embodiments of the present invention;

FIGS. 7 and 8 are cross-sectional diagrams of semiconductor structures that include SiGe layers according to yet further embodiments of the present invention;

FIG. 9 is a graph of the dislocation density near the surface of a strained silicon layer as a function of the boron concentration in the silicon substrate of a semiconductor structure according to certain embodiments of the present invention;

FIGS. 10A to 11B are transmission electron microscope (TEM) images illustrating the dislocation density near the surface of respective strained silicon layers; and

FIGS. 12A and 12B are TEM images illustrating the dislocation density in respective SiGe layers.

### DETAILED DESCRIPTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present.

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this disclosure and the relevant art and will not be interpreted in an idealized or overly formal sense unless expressly so defined herein.

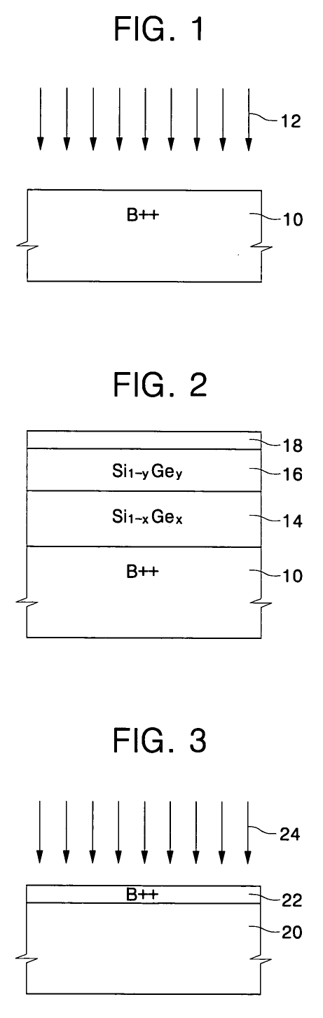

FIGS. 1 and 2 are cross-sectional diagrams of semiconductor structures according to certain embodiments of the present invention that include SiGe layers as virtual substrates.

As shown in FIG. 1, in these embodiments a silicon substrate 10 is provided. The silicon substrate 10 may be, for example, a P-type silicon substrate that is doped with boron (B) at a concentration as high as, for example, 10¹⁶/cm³ to 10²⁰/cm³. In certain embodiments of the present invention, the boron may be doped into the silicon substrate 10 during the fabrication of the silicon substrate 10, and may have a concentration as high as 10¹⁶/cm³ to 10²⁰/cm³. If the concentration of boron is, for example, 10¹⁵/cm³ or less, additional boron ions may be implanted into the silicon substrate 10 using an ion implantation process (indicated by the arrow 12 in FIG. 1). As described herein, the boron that is heavily doped into the silicon substrate 10 may suppress propagation of threading dislocations toward the surface.

As shown in FIG. 2, a graded SiGe layer 14 may be formed on the boron-doped silicon substrate 10. The graded SiGe layer 14 may be formed via, for example, an epitaxial growth process and may be formed to be a single crystalline SiGe layer. The concentration of germanium in the graded SiGe layer 14 increases with the height of the graded SiGe layer 14 above the silicon substrate 10 (i.e., the graded SiGe layer 14 has a “vertical germanium concentration gradient” in that the amount of germanium in the layer 14 increases with the height of the layer 14 above the substrate 10). For example, in certain embodiments of the present invention, the graded SiGe layer 14 may be represented by the equation, Si₁₋ₓGeₓ, where x may, for example, have the value 0 adjacent the interface between the silicon substrate 10 and the graded SiGe layer 14 and x may have a value of, for example, 0.15 to 0.4 at the upper surface of the graded SiGe layer 14. The thickness of the graded SiGe layer 14 may be, for example, about 0.1 μm to about 5 μm in certain embodiments of the present invention. The thickness of the graded SiGe layer 14 may vary with the germanium concentration gradient and/or the value of x. For example, if the germanium concentration gradient in the graded SiGe layer 14 is 1 μm/10% and the value of x is 0.2 (corresponding to a 20% germanium concentration), the graded SiGe layer 14 may be formed to have a thickness of 2 μm. The boron that is doped into the silicon substrate 10 may diffuse into the graded SiGe layer 14 during the formation of a graded SiGe layer 14 and/or during one or more subsequent heat treatments of the semiconductor structure.

As is also shown in FIG. 2, a relaxed SiGe layer 16 is formed on the graded SiGe layer 14. In certain embodiments of the present invention, the relaxed SiGe layer 16 may have a uniform or almost uniform germanium concentration. The relaxed SiGe layer 16 may be formed via, for example, an epitaxial growth process and may be formed to have a single crystalline structure. In certain embodiments of the present invention, the relaxed SiGe layer 16 may be represented by the equation Si_{1-y}Ge_{y}, where the value of y may be equal to the value of x at the upper surface of graded SiGe layer 14. In certain embodiments of the present invention, y may have a value between about 0.15 to about 0.4. The relaxed SiGe layer 16 may be formed to have a thickness, for example, of about 0.1 μm to about 2 μm. A strained silicon layer 18 may then be formed as a channel layer on the relaxed SiGe layer 16. The strained silicon layer 18 may be formed to have a thickness, for example, of about 10 nm to about 20 nm and may be formed using, for example, an epitaxial growth process.

As shown in FIG. 2, semiconductor structures according to certain embodiments of the present invention include a graded SiGe layer 14, a relaxed SiGe layer 16 and a strained silicon layer 18 that are sequentially stacked on a silicon substrate 10. The silicon substrate 10 may be doped with boron (B) at a concentration as high as, for example, 10¹⁶/cm³ to 10²⁰/cm³. The boron in the silicon substrate 10 may diffuse into the graded SiGe layer 14 during the formation of the layers 14, 16 and 18 and/or during subsequent heat treatment of part or all of the semiconductor structure. As is known to those of skill in the art, misfit threading dislocations may arise adjacent to the lower surface of the graded SiGe layer 14 due to the lattice mismatch between the graded SiGe layer 14 and the silicon substrate 10. Boron that diffuses into the graded SiGe layer 14 may suppress movement of these dislocations toward the upper surface of the graded SiGe layer 14, and thus the boron that is heavily doped into the silicon substrate 10 may facilitate reducing the density of threading dislocations near the surface of the strained silicon layer 18.

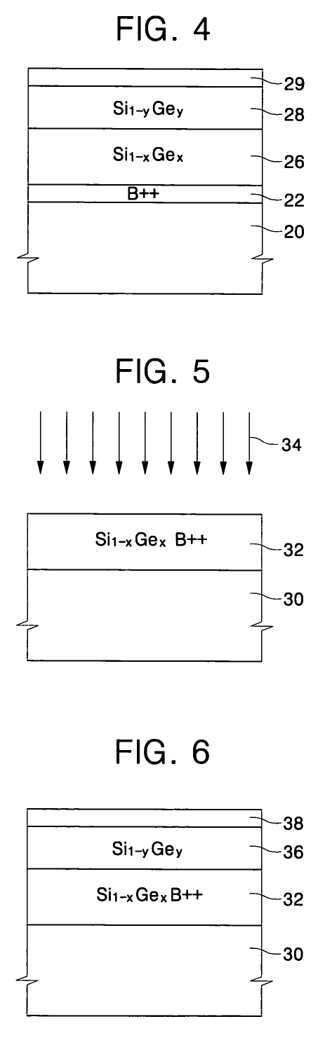

FIGS. 3 and 4 are cross-sectional diagrams of a semiconductor structure that includes a SiGe layer as a virtual substrate according to further embodiments of the present invention.

As shown in FIG. 3, a single crystalline silicon layer 22 is formed on a silicon substrate 20. The single crystal silicon layer 22 may be doped with boron at a concentration as high as 10¹⁶/cm³ to 10²⁰/cm³. The silicon substrate 20 may, for example, be a P-type silicon substrate. The silicon substrate 20 may be doped with boron at a concentration of about 10¹⁵/cm³ or less. The single crystalline silicon layer 22 may be formed, for example, using an epitaxial growth process. In certain embodiments, the boron may be doped into the single crystalline silicon layer 22 using an ion implantation process 24, as shown in FIG. 3. In other embodiments, the boron may be doped in situ using a reaction gas such as, for example, diborane (B₂H₆) during the epitaxial growth of the single crystalline silicon layer 22.

As shown in FIG. 4, a graded SiGe layer 26, a relaxed SiGe layer 28 and a strained silicon layer 29 may be sequentially formed on the single crystalline silicon layer 22. Layers 26, 28 and 29 may be formed, for example, using the same processes used to form layers 14, 16 and 18 of the semiconductor structure illustrated in FIG. 2. The single crystalline silicon layer 22 may be doped with boron (B) at a concentration as high as 10¹⁶/cm³ to 10²⁰/cm³. The boron in the single crystalline silicon layer 22 may diffuse into the graded SiGe layer 26 during the formation of one or more of the layers 26, 28 and 29 and/or during subsequent heat treatments. The boron that diffuses into the graded SiGe layer 26 may suppress movement of misfit dislocations that occur adjacent the lower surface of the graded SiGe layer 26 toward the surface of the graded SiGe layer 26. As a result, the density of threading dislocations near the surface of the strained silicon layer 29 may be reduced.

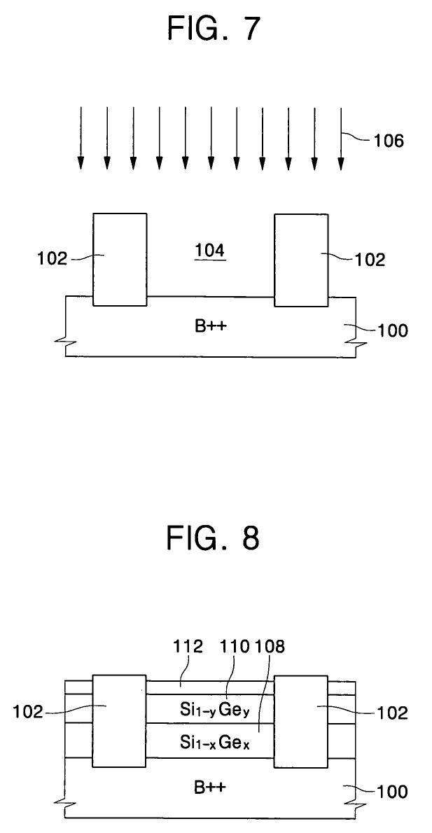

FIGS. 5 and 6 are cross-sectional diagrams of a semiconductor structure that includes a SiGe layer as a virtual substrate according to yet further embodiments of the present invention.

As shown in FIG. 5, a graded SiGe layer 32 is formed on a silicon substrate 30 using, for example, an epitaxial growth process. Boron is directly doped into the graded SiGe layer 32. In certain embodiments, the boron is doped into the graded SiGe layer 32 using an ion implantation process 34 as shown in FIG. 5. Alternatively, the boron may be doped in situ using a reaction gas such as, for example, diborane (B₂H₆) during the formation of the graded SiGe layer 32. The boron concentration in the graded SiGe layer 32 may, for example, be between about 10¹²/cm³ to about 10²⁰/cm³. The thickness and composition of the graded SiGe layer 32 may, for example, be similar to the thickness and composition of the graded SiGe layer 14 described above with respect to the embodiment depicted in FIG. 2.

As shown in FIG. 6, a relaxed SiGe layer 36 and a strained silicon layer 38 may be sequentially formed on the graded SiGe layer 32 using, for example, the processes used to form the relaxed SiGe layer 16 and the strained silicon layer 18 of the embodiment depicted in FIG. 2. The boron doped at a concentration as high as 10¹²/cm³ to 10²⁰/cm³ into the graded SiGe layer 32 may serve to suppress movement of misfit dislocations occurring adjacent the interface between the graded SiGe layer 32 and the silicon substrate 30 toward the upper surface of the graded SiGe layer 32, thereby reducing the density of threading dislocations near the surface of the strained silicon layer 38.

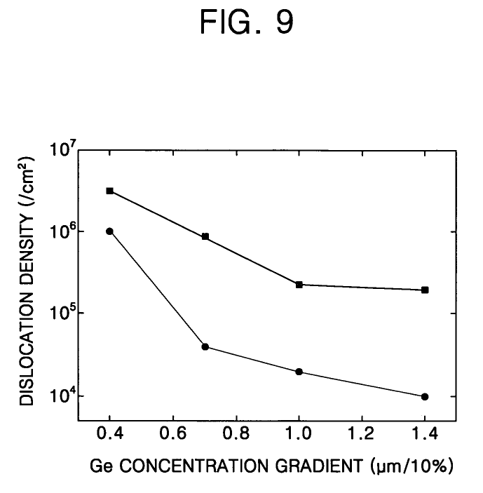

FIGS. 7 and 8 are cross-sectional diagrams of a semiconductor structure that includes a SiGe layer as a virtual substrate according to still further embodiments of the present invention.

In the embodiments of FIGS. 7 and 8, respective layers as illustrated in FIG. 2 are sequentially formed on a bottom surface of an active trench 104 that is provided between isolation layers 102 using, for example, selective epitaxial growth techniques. The isolation layers 102 may be formed in a silicon substrate 100, for example, using a known shallow trench isolation process to define an active region. The isolation layer 102 may be formed, for example, as a silicon oxide layer. The active region defined by the isolation layer 102 may be selectively anisotropically etched to form the active trench 104. The silicon substrate 100 may be a P-type semiconductor substrate doped with boron B at a concentration as high as, for example, 10¹⁶/cm³ to 10²⁰/cm³. Boron may be doped into the silicon substrate 100 during the fabrication of the silicon substrate 100. If the silicon substrate 100, as fabricated, contains boron at a concentration of about 10¹⁵/cm³ or less, boron ions may also be implanted into the silicon substrate 100 by an ion implantation process 106 after the active trench 104 is formed, as shown in FIG. 7.

As shown in FIG. 8, a graded SiGe layer 108, a relaxed SiGe layer 110 and a strained silicon layer 112 are sequentially formed in the active trench 104. The layers 108, 110 and 112 may be formed using, for example, selective epitaxial growth techniques that suppress growth on the isolation layer 102. The graded SiGe layer 108, the relaxed SiGe layer 110 and the strained silicon layer 112 may be formed, for example, to have the same composition as the graded SiGe layer 14, the relaxed SiGe layer 16 and the strained silicon layer 18, respectively, of the embodiment depicted in FIG. 2. The graded SiGe layer 108 may be formed to have a thickness of, for example, about 100 nm to about 500 nm. By way of example, when the germanium concentration gradient in the graded SiGe layer 108 is 100 nm/10% and x is 0.2, the graded SiGe layer 108 may have a thickness of about 200 nm. The relaxed SiGe layer 110 may be formed to have a thickness of, for example, about 100 nm to about 200 nm. The strained silicon layer 112 may be formed to have a thickness of, for example, about 10 nm to about 20 nm.

Although not shown in the drawings, according to yet further embodiments of the present invention the respective layers 22, 26, 28 and 29 illustrated in FIG. 4 or the respective layers 32, 36 and 38 illustrated in FIG. 6 may be sequentially formed on a bottom surface of the active trench 104 that is defined by the isolation layer 102 in the semiconductor structure illustrated in FIG. 7. In such embodiments, the graded SiGe layers 26 and 32 may be formed to have a thickness of, for example, about 100 nm to about 500 nm, and the relaxed SiGe layers 28 and 36 may be formed to have a thickness of, for example, about 100 nm to about 200 nm. The strained silicon layers 29 and 38 may be formed to have a thickness of, for example, about 10 nm to about 20 nm.

### EXPERIMENTAL EXAMPLES

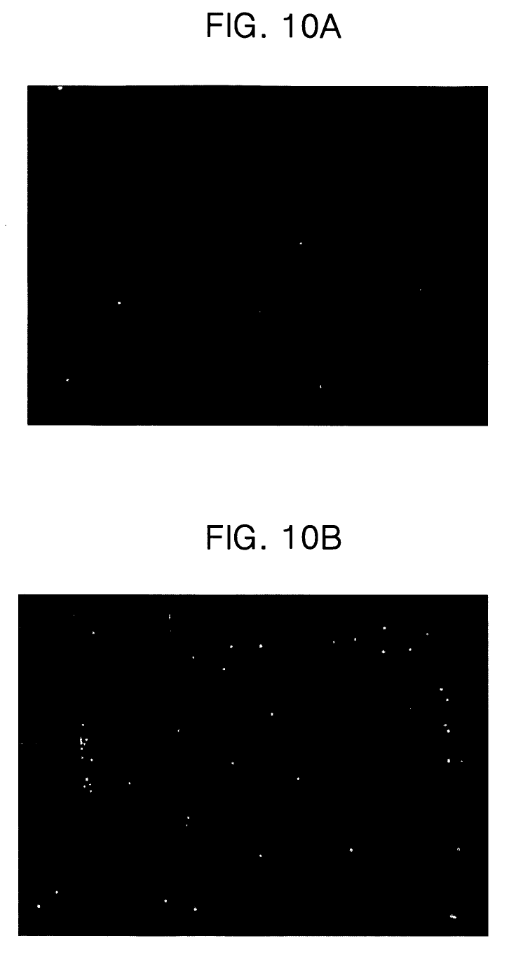

FIG. 9 is a graph of the dislocation density near the upper surface of a strained silicon layer of a semiconductor structure fabricated in accordance with embodiments of the present invention. In FIG. 9, the x-axis indicates the germanium concentration gradient in a graded SiGe layer of the semiconductor structure, and the y-axis indicates the dislocation density near the surface of the strained silicon layer. Here, the data points represented by a “●” (solid circle) show results that were obtained by sequentially forming a graded SiGe layer, a relaxed SiGe layer and a strained silicon layer on a silicon substrate doped with boron at a concentration of about 10¹⁹/cm³ according to exemplary embodiments of the present invention. The data points represented by a “▪” (solid square) show results that were obtained by sequentially forming a graded SiGe layer, a relaxed SiGe layer and a strained silicon layer on a silicon substrate doped with boron at a concentration of about 10¹⁵/cm³.

The experimental results represented by the “●” (solid square) correspond to four semiconductor structures that were formed in accordance with embodiments of the present invention in which the graded SiGe layers have a germanium concentration of about 20% at the upper surface of the graded SiGe layer. The germanium concentration gradients in the four structures were 0.4 μm/10%, 0.7 μm/10%, 1.0 μm/10% and 1.4 μm/10%, respectively. In each of these structures, the relaxed SiGe layer was formed to have a germanium concentration of 20% and a thickness of 1 μm. The strained silicon layer in each structure had a thickness of 20 nm.

As shown in FIG. 9, the semiconductor structures according to embodiments of the present invention have a relatively smaller threading dislocation density near the surface of the strained silicon layer as compared to the semiconductor structures having silicon substrates doped with boron at a concentration of 10¹⁵/cm³.

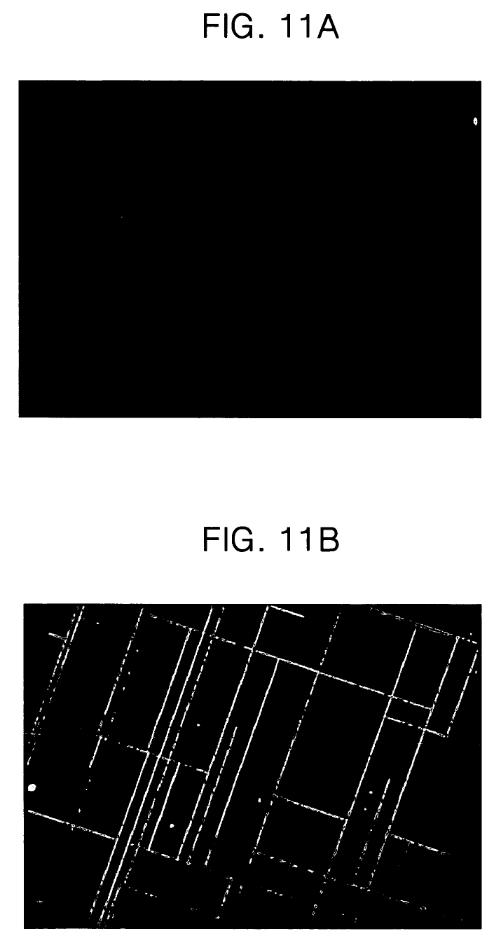

FIGS. 10A to 11B are transmission electron microscope (TEM) images that illustrate the density of threading dislocations near the upper surface of a strained silicon layer as a function of the boron concentration in the silicon substrate.

The photographs in FIGS. 10A and 11A show the dislocation density in semiconductor structures in which a graded SiGe layer, a relaxed SiGe layer and a strained silicon layer were formed on a silicon substrate doped with boron at a concentration of about 10¹⁹/cm³. In these semiconductor structures, the graded SiGe layers were formed to have a concentration gradient of 1 μm/10%. In the semiconductor structure corresponding to FIG. 10A, the peak germanium concentration in the SiGe layer was about 20%, and the germanium concentration in the relaxed SiGe layer was also 20%. In the semiconductor structure corresponding to FIG. 11A, the peak germanium concentration was about 25%, and the germanium concentration of the relaxed SiGe layer was also 25%. The relaxed SiGe layer in each of these semiconductor structures had a thickness of about 1 μm, and each of the strained silicon layers had a thickness of about 20 nm.

The TEM images of FIGS. 10B and 11B show the dislocation density in semiconductor structures that were identical the semiconductor structures of FIGS. 10A and 11A, respectively, except that in the structures corresponding to FIGS. 10B and 11B the silicon substrate was doped with boron at a concentration of about 10¹⁵/cm³. The TEM images of FIGS. 10A, 10B, 11A and 11B were taken after etching the surface of the respective strained silicon layers using a mixture of chromic acid (CrO₃) and hydrofluoric acid (HF) for 30 seconds.

FIGS. 10A, 10B, 11A and 11B confirm the results shown in FIG. 9. Specifically, these figures show that the semiconductor structures with silicon substrates doped with boron at a concentration of about 10¹⁹/cm³ have relatively fewer threading dislocations near the surface of the strained silicon layer as compared to the semiconductor structures with silicon substrates doped with boron at a concentration of about 10¹⁵/cm³.

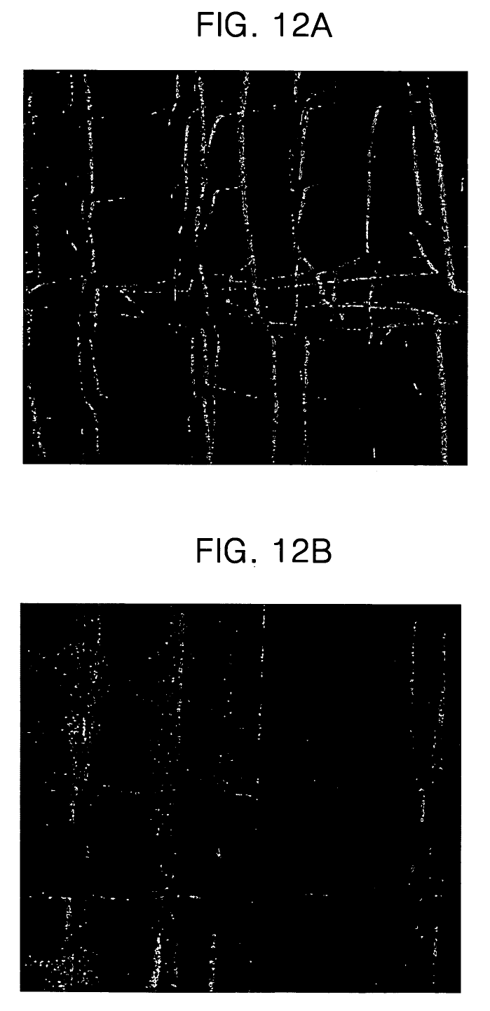

FIGS. 12A and 12B are TEM images of the graded SiGe layers of semiconductor structures that were formed in the same manner as the semiconductor structures discussed above with respect to FIGS. 10A and 10B, respectively. The semiconductor structures of FIGS. 12A and 12B were polished to expose the respective graded SiGe layers. Thus, FIG. 12A is a TEM image showing, in plan view, a graded SiGe layer formed on a silicon substrate doped with boron at a concentration of about 10¹⁹/cm³, and FIG. 12B is a TEM image showing, in plan view, a graded SiGe layer formed on a silicon substrate doped with boron at a concentration of about 10¹⁵/cm³.

As shown in FIGS. 12A and 12B, the dislocation density in the graded SiGe layer may be relatively greater in the semiconductor structure that has a silicon substrate doped with boron at a concentration of about 10¹⁹/cm³ as compared to the semiconductor structure that has a silicon substrate doped with boron at a concentration of about 10¹⁵/cm³. Thus FIGS. 12A and 12B show that a relatively high density of misfit dislocations may be present in a graded SiGe layer that is formed on a silicon substrate that is heavily doped with boron, thereby sufficiently relaxing the graded SiGe layer. Further, the images of FIGS. 10A, 10B, 12A and 12B show that when the silicon substrate is doped with boron at a concentration of about 10¹⁹/cm³, the dislocation density in the graded SiGe layer may be relatively greater as compared to the case where the silicon substrate is doped with boron at a concentration of about 10¹⁵/cm³, but the density of threading dislocations in the strained silicon layer may be reduced. These results indicate that doping the silicon substrate at a higher concentration may suppress movement of the misfit dislocations toward upper layers of the device.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. A semiconductor structure comprising:
a silicon layer;
a silicon-germanium layer on the silicon layer; and
a strained silicon layer on the silicon-germanium layer;
wherein at least one of the silicon layer and/or the silicon-germanium layer is heavily doped with impurities.

2. The semiconductor structure of claim 1, wherein the impurities comprise boron.

3. The semiconductor structure of claim 2, wherein the silicon layer has a boron concentration of between about 10¹⁶/cm³ and about 10²⁰/cm³.

4. The semiconductor structure of claim 3, wherein the silicon-germanium layer has a boron concentration of between about 10¹²/cm³ and 10²⁰/cm³.

5. The semiconductor structure of claim 3, wherein the silicon layer comprises a silicon substrate.

6. The semiconductor structure of claim 4, wherein the silicon layer comprises a single crystalline silicon layer on a silicon substrate.

7. The semiconductor structure of claim 1, wherein the silicon-germanium layer comprises:
a graded silicon-germanium layer that has a vertical germanium concentration gradient on the silicon layer; and
a uniform silicon-germanium layer that has a substantially uniform germanium concentration on the graded silicon-germanium.

8. The semiconductor structure of claim 1, wherein at least the graded silicon-germanium layer has a boron concentration of between about 10¹²/cm³ and about 10²⁰/cm³.

9. The semiconductor structure of claim 7, wherein the graded silicon-germanium layer is represented by the chemical equation Si₁₋ₓGeₓ, where x has a value of approximately zero adjacent an interface between the silicon layer and the graded silicon-germanium layer and a value between about 0.15 and about 0.4 adjacent an interface between the graded silicon-germanium layer and the relaxed silicon-germanium layer.

10. The semiconductor structure of claim 9, wherein the relaxed silicon-germanium layer is represented by the chemical equation Si_{1-y}Ge_{y}, where y is approximately equal to the value of x at the interface between the graded silicon-germanium layer and the relaxed silicon-germanium layer.

11. The semiconductor structure of claim 1, wherein the strained silicon layer is a single crystalline silicon layer having a thickness of about 10 nm to about 20 nm.

12. The semiconductor structure of claim 7, wherein the graded silicon-germanium layer has a thickness of between about 0.1 microns and about 5 microns.

13. The semiconductor structure of claim 7, wherein the relaxed silicon-germanium layer has a thickness of between about 0.1 microns and about 2 microns.

14. The semiconductor structure of claim 1, wherein the vertical germanium concentration gradient in the graded silicon-germanium layer is between about 0.1 microns/10% and about 2.0 microns/10%.

15. The semiconductor structure of claim 8, wherein the upper surface of the strained silicon layer has a dislocation density of less than 10⁵ dislocations per square centimeter.

16. The semiconductor structure of claim 7, wherein the uniform silicon-germanium layer comprises a relaxed silicon-germanium layer.

17. A method of fabricating a semiconductor structure, the method comprising:
preparing a silicon layer;
forming a silicon-germanium layer on the silicon layer; and
forming a strained silicon layer on the silicon-germanium layer;
wherein at least one of the silicon layer and/or the silicon-germanium layer is heavily doped with impurities.

18. The method of claim 17, wherein the impurities comprise boron.

19. The method of claim 18, wherein the boron in the silicon layer has a concentration of between about 10¹⁶/cm³ to about 10²⁰/cm³.

20. The method of claim 19, wherein preparing the silicon layer comprises implanting boron ions into a silicon substrate.

21. The method of claim 19, wherein preparing the silicon layer comprises:
forming a single crystalline silicon layer on a silicon substrate; and
implanting boron ions into the single crystalline silicon layer.

22. The method of claim 19, wherein preparing the silicon layer comprises doping boron ions in situ during the epitaxial growth of a single crystalline silicon layer on a silicon substrate.

23. The method of claim 17, wherein forming the silicon-germanium layer on the silicon layer comprises:
forming a graded silicon-germanium layer that has a vertical germanium concentration gradient on the silicon layer; and
forming a relaxed silicon-germanium layer that has a substantially uniform germanium concentration on the graded silicon-germanium layer.

24. The method of claim 23, wherein the graded silicon-germanium layer and the relaxed silicon-germanium layer are represented by chemical equations, Si₁₋ₓGeₓ and Si_{1-y}Ge_{y}, respectively, where x has a value of approximately zero adjacent an interface between the silicon layer and the graded silicon-germanium layer and y adjacent an interface between the graded silicon-germanium layer and the relaxed silicon-germanium layer, and wherein y has a value of 0.15 to 0.4.

25. The method of claim 17, wherein forming a strained silicon layer on the silicon-germanium layer comprises epitaxially growing a strained single crystalline silicon layer on the silicon-germanium layer to a thickness of about 10 nm to about 20 nm.

26. The method of claim 17, wherein the silicon layer comprises a silicon substrate, and wherein forming the silicon-germanium layer on the silicon layer comprises forming the silicon-germanium layer to have a boron concentration of about 10¹²/cm³ to about 10²⁰/cm³ on the silicon substrate.

27. The method of claim 23, wherein at least the graded silicon-germanium layer has a boron concentration of between about 10¹²/cm³ to 10²⁰/cm³.

28. The method of claim 27, wherein forming the graded silicon-germanium layer that has a vertical germanium concentration gradient on the silicon layer comprises:
forming the graded silicon-germanium layer on the silicon layer to have vertical germanium concentration gradient; and
implanting boron ions into the graded silicon-germanium layer.

29. The method of claim 27, wherein forming the graded silicon-germanium layer that has a vertical germanium concentration gradient on the silicon layer comprises:
doping boron ions in situ while forming the graded silicon-germanium layer on the silicon layer to have vertical germanium concentration gradient.

30. A semiconductor structure, comprising:
a silicon substrate;
a graded silicon-germanium layer on the silicon substrate;
a relaxed silicon-germanium layer on the graded silicon-germanium layer; and
a strained silicon layer on the relaxed silicon-germanium layer;
wherein at least one of the silicon layer or the graded silicon-germanium layer is doped to have a boron concentration of at least about 10¹²/cm³.

31. The semiconductor structure of claim 30, wherein the graded silicon-germanium layer is represented by the chemical equation Si₁₋ₓGeₓ, where x has a value of approximately zero adjacent an interface between the silicon layer and the graded silicon-germanium layer and a value between about 0.15 and about 0.4 adjacent an interface between the grfaded silicon-germanium layer and the relaxed silicon-germanium layer; and wherein the relaxed silicon-germanium layer is represented by the chemical equation Si_{1-y}Ge_{y}, where y is approximately equal to the value of x at the interface between the graded silicon-germanium layer and the relaxed silicon-germanium layer.

32. The semiconductor structure of claim 31, wherein the strained silicon layer is a single crystalline silicon layer having a thickness of about 10 nm to about 20 nm, the graded silicon-germanium layer has a thickness of between about 0.1 micron to about 5 microns and the relaxed silicon-germanium layer has a thickness of between about 1 micron to about 2 microns.

33. The semiconductor structure of claim 30, wherein the vertical germanium concentration gradient in the graded silicon-germanium layer is between about 0.1 microns/10% to about 2.0 microns/10%.

34. The semiconductor structure of claim 30, wherein the upper surface of the strained silicon layer has a dislocation density of less than 10⁵ dislocations per square centimeter.
